(19) United States
(12) Patent Application Publication
(10) Pub. No.: US 2006/0092739 A1
(43) Pub. Date: May 4, 2006

(54) Semiconductor memory device

(75) Inventors: Katsuyuki Fujita, Yokohama-shi (JP); Tomoki Higashi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/252,627

(22) Filed: Oct. 19, 2005

(30) Foreign Application Priority Data
Oct. 28, 2004 (JP) 2004-314014

(51) Int. Cl. G11C 7/02

(52) U.S. Cl. 365/210

(57) ABSTRACT

A semiconductor memory device has memory cells each of which has a MIS type of transistor capable of setting one of two kinds of threshold potentials, reference cells used for determining data stored in the memory cells, which have the same size, shape and electrical properties as those of the memory cells, word lines connected to gates of the memory cells, reference word lines connected to gates of the reference cells, source line contacts connected to sources of the memory cells and the reference cells, and bit line contacts connected to drains of the memory cells and the reference cells, arrangement order of the source line contact, the word line and bit line contact connected to each of the memory cells is equal to arrangement order of the source line contact, the reference word line and the bit line contact connected to the reference cell corresponding to the memory cell.

### CROSS REFERENCE TO RELATED APPLICATIONS

This application claims benefit of priority under 35USC§119 to Japanese Patent Application No. 2004-314014, filed on Oct. 28, 2004, the entire contents of which are incorporated by reference herein.

### BACKGROUND OF THE INVENTION

1. Field of the Invention

The present invention relates to a semiconductor memory device which determines logics of data stored in a memory cell by comparing a data potential of the memory cell with that of a reference cell.

2. Related Art

There is proposed a Floating Body Cell (FBC) which accumulates majority carriers in a floating body (hereinafter referred to as a body) of a transistor formed on Silicon On Insulator (SOI) and the like, as a memory cell alternative to a DRAM cell which stores data in a capacitor.

In the FBC, at the time of writing “1”, the transistor performs a pentode operation to accumulate holes generated by impact ionization in a body, so that the potential of the body is raised to lower the threshold voltage of the transistor. At the time of writing “0”, the holes accumulated in the body are discharged by forward-biasing a PN diode between the body and the drain, so that the potential of the body is lowered to raise the threshold voltage of the transistor.

In the FBC, a bit line contact and a source line contact are used in common between adjacent cells in order to reduce the cell area. More specifically, there are provided two types of FBCs in a memory cell array. In one type of these FBCs, source line contacts are arranged on the left side of word lines arranged in a row, and bit line contacts are arranged on right side of the word lines. In the other type of these FBCs, bit line contacts are arranged on the left side of word lines, and source line contacts are arranged on right side of the word lines.

If such FBCs can be manufactured with the same accuracy as a design drawing, there is no problem, but in practice, alignment errors and shortening of a pattern occur in a lithography process, causing differences in gate-drain length and gate-source length between adjacent cells. The above described two kinds of FBCs in the memory cell array have different arrangement orders with respect to the source line contact, the word line and the bit line contact. Therefore, in these FBCs, a resistance of a diffusion layer between the source line contact and a channel and a resistance of a diffusion layer between the bit line contact and the channel are different from each other, and Vg-Id characteristics is also different from each other.

Due to such positional deviation at the time of manufacture, FBCs having two different characteristics in the memory cell array are mixed up.

In the conventional semiconductor memory in which a dummy cell is used to read data written in the body of FBC, the characteristics of the dummy cell and the FBC to be read are significantly different from each other due to the above described size difference. As a result, wrong data may be read (see Japanese Patent Laid-Open No. 2003-68877).

Furthermore, in the conventional semiconductor memory in which a dummy cell is provided for each word line, the above described problem of alignment error at the time of manufacture can be eliminated, but a sense amplifier needs to be provided for each bit line, which increases the number of sense amplifiers, thereby making it difficult to have a practical use.

### SUMMARY OF THE INVENTION

According to one embodiment of a semiconductor memory device, comprising:

memory cells each of which has a MIS type of transistor capable of setting one of two kinds of threshold potentials;

reference cells used for determining data stored in the memory cells, which have the same size, shape and electrical properties as those of the memory cells;

word lines connected to gates of the memory cells;

reference word lines connected to gates of the reference cells;

source line contacts connected to sources of the memory cells and the reference cells; and

bit line contacts connected to drains of the memory cells and the reference cells,

arrangement order of the source line contact, the word line and bit line contact connected to each of the memory cells is equal to arrangement order of the source line contact, the reference word line and the bit line contact connected to the reference cell corresponding to the memory cell.

### BRIEF DESCRIPTION OF THE DRAWINGS

FIG. 1 is a circuit diagram showing a schematic configuration of a semiconductor memory device according to a first embodiment of the present invention.

FIG. 2 is a diagram showing one example of a layout of FIG. 1.

FIG. 3 is a cross-sectional view showing a cross-sectional structure of an example of an FBC having a back gate.

FIG. 4 is a diagram showing one example of a cross-sectional structure of an example of an FBC having a back gate.

FIG. 5 is a layout diagram showing one example in which alignment error occurred.

FIG. 6 is a circuit diagram showing a schematic configuration of a semiconductor memory device according to a second embodiment.

FIG. 7 is a diagram showing one example of a layout of FIG. 6.

### DETAILED DESCRIPTION OF THE INVENTION

In the following, embodiments according to the present invention will be described with reference to the accompanying drawings.

### FIRST EMBODIMENT

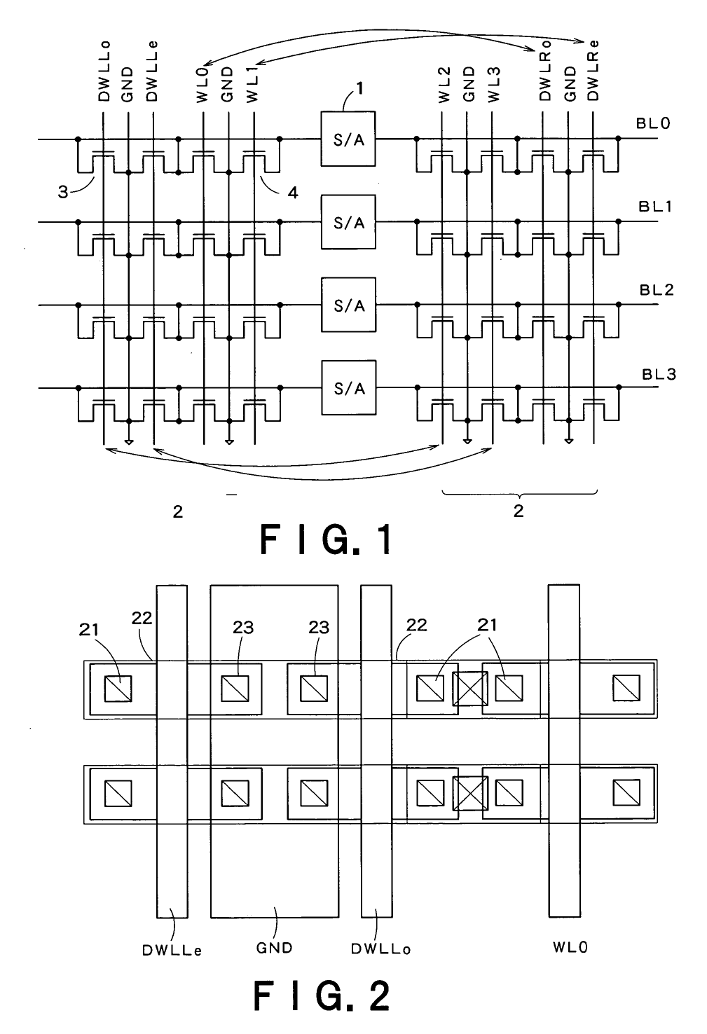

FIG. 1 is a circuit diagram showing a schematic configuration of a semiconductor memory device according to a first embodiment of the present invention, and FIG. 2 shows an example of a layout in FIG. 1.

In the semiconductor memory device shown in FIG. 1, an OPEN-BL system is adopted, in which memory cell arrays 2 are arranged on both sides of sense amplifiers (S/A) 1. The memory cell array 2 has a plurality of word lines WL0, WL1, WL2, WL3, a plurality of dummy word lines DWLLo, DWLLe, DWLRo, DWLRe, a plurality of bit lines BL0 to BL3 arranged in the direction which crosses to the word lines and the dummy word lines, and FBCs 3, 4 formed in the vicinity of intersections of the word lines and the bit lines. In the following, the FBC on the dummy word line is referred to as a dummy cell 3, and the other cell for writing data is referred to as a memory cell 4. The dummy cell 3 and the memory cell 4 are composed of MIS type of transistors, and have the same size, shape and electrical properties.

In the example shown in FIG. 1, two word lines WL0, WL1, and two dummy word lines DWLLe, DWLLo are arranged on the left side of the sense amplifier 1, and two word lines WL2, WL3, and two dummy word lines DWLRe, DWLRo are arranged on the right side of the sense amplifier 1.

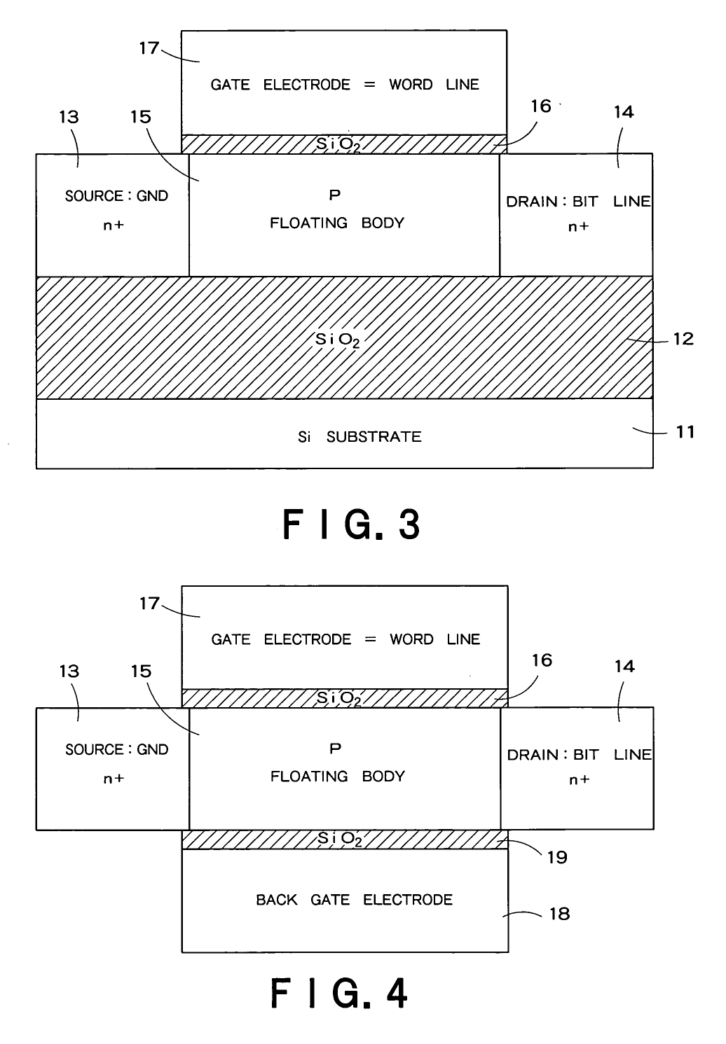

The FBC 3, 4 have a cross-sectional structure, for example, as shown in FIG. 3. On a silicon substrate 11, there is formed an insulating film 12, such as a silicon oxide film, on the top surface of which n-diffusion layers 13, 14, and a p-diffusion layer 15, each separated from the silicon substrate 11, are formed. The n-diffusion layers 13, 14 serve as a source region and a drain region respectively, and the p-diffusion layer 15 serves as a channel body. A gate electrode 17 is formed on the top surface of the p-diffusion layer 15 via a gate insulating film 16. An SOI substrate is used as a material of the substrate in FBC 3, 4.

FIG. 4 is a figure showing an example of a cross-sectional structure of the FBC having a back gate. The FBC shown in FIG. 4 is provided with a floating body 15 formed on the top surface of a back gate electrode 18 via an insulating film 19 such as SiO₂. A gate electrode 17 is arranged via the gate insulating film 16 on the floating body 15.

The FBCs 3, 4 in FIG. 1 may have the same structure as that of FIG. 3, or the same structure as that of FIG. 4.

The FBCs 3, 4 shown in FIG. 1 has bit line contacts 21 connected to the bit lines and gates 22 connected to the word lines, and source line contacts 23 connected to grounding conductors, as shown in FIG. 2. In one of the FBCs 3, 4 adjacent in the right and left directions in FIG. 1, the bit line contact 21, the gate 22, and the source line contact 23 are arranged in order. In the other of the FBCs, the source line contact 23, gate 22, and the bit line contact 21 are arranged in order. In this way, the FBCs 3, 4 adjacently arranged in the right and left directions are different from each other in arrangement order of the source, the gate and the drain.

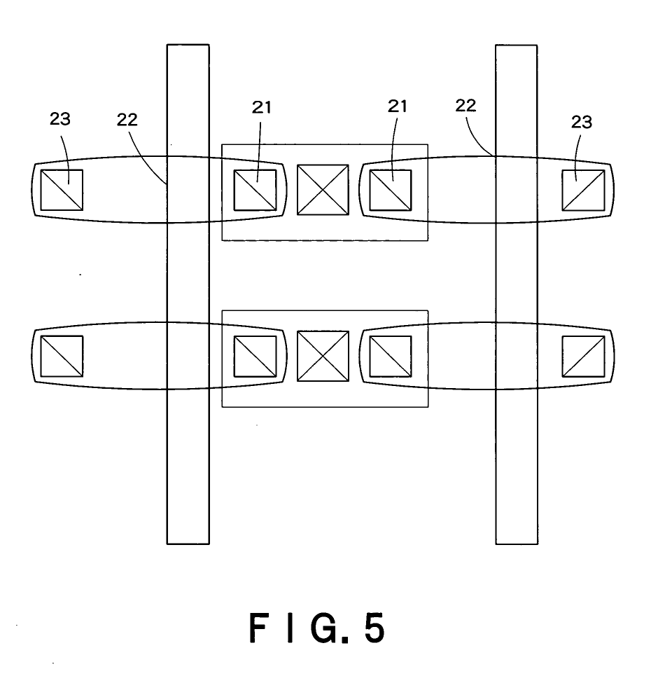

FIG. 2 shows an ideal layout arrangement of the FBCs 3, 4. When alignment errors of a mask pattern and the like occur in a lithography process, a difference between a distance between the bit line contact 21 and the gate 22 and a distance between the gate 22 and the source line contact 23 occurs in the two adjacent FBCs, as shown in FIG. 5.

Accordingly, in the present embodiment, the arrangement order of the bit line contact 21, the gate 22, and the source line contact 23 is the same in the dummy cell 3 and the memory cell 4. Specifically, the memory cell 4 on the second word line WL0 on the left side of the sense amplifier 1 shown in FIG. 1, is associated with the third dummy word line DWLRe on the right side. Similarly, the memory cell 4 on the first word line WL1 on the left side of the sense amplifier 1 is associated with the fourth dummy word line DWLRo on the right side.

Similarly, the memory cell 4 on the first word line WL2 on the right side of the sense amplifier 1 is associated with the third dummy word line DWLLo on the left side. Similarly, the memory cell 4 on the second word line WL3 on the right side of the sense amplifier 1 is associated with the fourth dummy word line DWLLe on the left side.

In this way, the dummy cell 3 corresponding to the memory cell 4 connected to the word line at even number order crossing to one bit line of the bit line pair arranged on both sides of the sense amplifier 1 is connected to the dummy word line at odd number order crossing to the other bit line. The dummy cell corresponding to the memory cell 4 connected to the word line at odd number order crossing to one bit line is connected to the dummy word line at even number order crossing to the other bit line.

FIG. 1 shows one example in which two word lines and two dummy word lines are arranged on each side of the sense amplifiers 1. However, the number of the word lines and the number of the dummy word lines are not limited. It is desirable that the number of word lines is equal on each side of the sense amplifiers 1, and the number of dummy word lines is equal on each side of the sense amplifiers 1. The different memory cells 4 may share the same dummy cell 3.

As described above, in the first embodiment, when the memory cell 4 to be read out has the arrangement order of the bit line contact 21, the gate 22 and the source line contact 23, data is read out by using the dummy cell 3 which has the same arrangement order, i.e. the arrangement order of the bit line contact 21, the gate 22 and the source line contact 23. On the other hand, when the memory cell 4 to be read out has the arrangement order of the source line contact 23, the gate 22 and the bit line contact 21, data is read out by using the dummy cell 3 which has the same arrangement order, i.e. the arrangement order of the source line contact 23, the gate 22 and the bit line contact 21.

By conforming the arrangement order, it is possible to conform electrical properties such as Vg-Id, in the memory cell 4 to be read out and the dummy cell 4, thereby correctly reading out data of the memory cell 4.

### SECOND EMBODIMENT

A second embodiment is characterized in that a FOLDED-BL system is adopted.

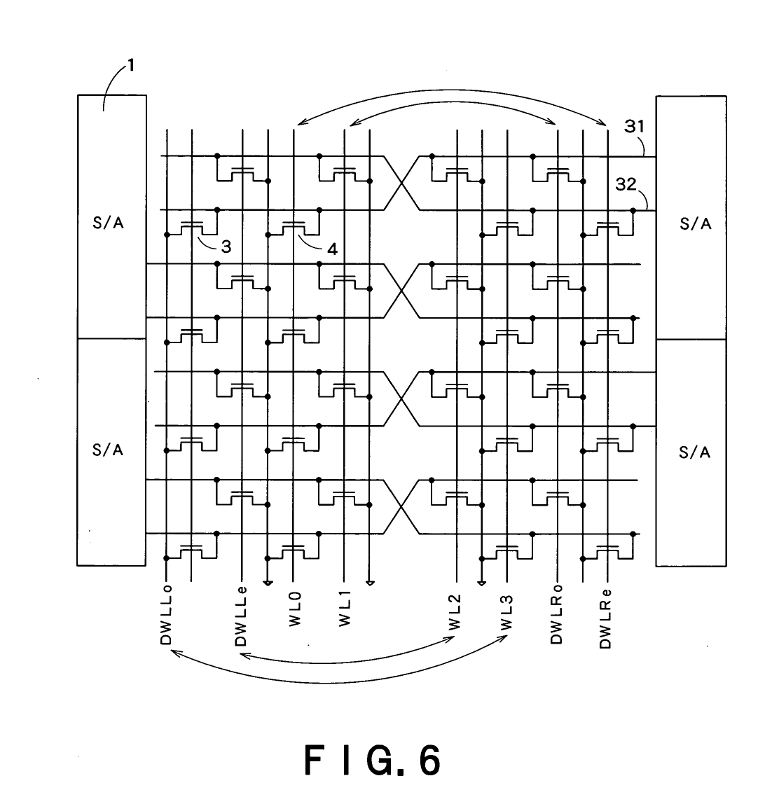

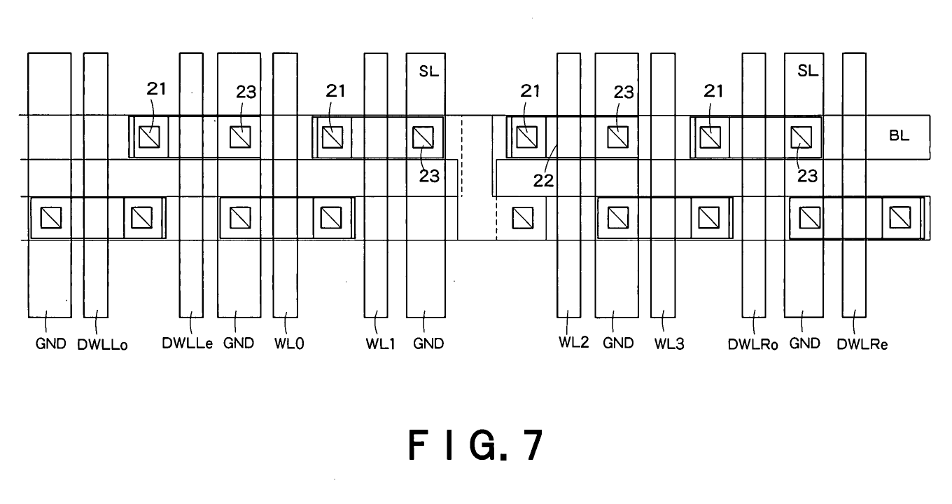

FIG. 6 is a circuit diagram showing a schematic configuration of a semiconductor memory device according to the second embodiment of the present invention, and FIG. 7 shows an example of a layout of FIG. 6.

The semiconductor memory device shown in FIG. 6 has sense amplifiers 1 provided on both sides, a plurality of bit line pairs 31, 32 alternately arranged on the inside of the sense amplifiers, a plurality of word lines WL0 to WL3, a plurality of dummy word lines DWLLo, DWLLe, DWLRo, DWLRe, which word lines are arranged in the direction which crosses to the bit line pairs, and FBCs 3, 4 formed in the vicinity of cross points of the bit lines and the word lines. The system in which bit line pairs are alternately arranged on the inside of the sense amplifiers 1 provided on both sides, as shown in FIG. 6, is referred to as the FOLDED-BL system.

The FBCs 4 are memory cells to be read out, and the FBCs 3 are dummy cells used for determining data of the memory cells 4. The dummy cell 3 and the corresponding memory cells 4 are connected to both of two bit lines composing of a bit line pair. The dummy cells 3 and the memory cells 4 have the same size, shape and electrical properties.

The FBCs 3 and the dummy cells 4 connected to one bit line 31 of the bit line pair have the arrangement order of the bit line contact 21, the word line (dummy word line) and the source line contact 23, respectively. The FBCs 3 and the dummy cells 4 connected to the other bit line 31 of the bit line pair has the other arrangement order of the source line contact 23, the word line (dummy word line) and the bit line contact 21.

In this way, one bit line 31 and the other bit line 32 of the bit line pair have different arrangement orders from each other. Therefore, it is impossible to conform the arrangement order in the bit lines 31, 23.

Because of this, in FIG. 6, the bit line pairs 31, 32 are crossed to each other in an intermediate point between the sense amplifiers 1 on both sides. The bit line pairs 31, 32 are connected to a wiring layer arranged on an upper layer or a lower layer via a contact so that both bit lines are not short-circuited.

By crossing the bit lines 31, 32, similarly to the first embodiment, it is possible to conform the arrangement order of the source line contact, the word line and the bit line contact in the dummy cells 3 and the memory cells to be read out.

In FIG. 6, when the memory cell 4 on the word line WL0 is read out, the dummy cell on the dummy word line DWLRe is used. When the memory cell 4 on the word line WL1 is read out, the dummy cell 3 on the dummy word line DWLRo is used. The memory cells 4 connected to the word lines WL0, WL1 and the dummy cells 3 connected to the dummy word lines DWLLo, DWLLe has the arrangement order of the bit line contact 21, the word line (or reference word line) and the source line contact.

When the memory cell 4 on the word line WL2 is read out, the dummy cell 3 on the dummy word line DWLLe is used. When the memory cell 4 on the word line WL3 is read out, the dummy cell 3 on the dummy word line DWLLo is used. The memory cells 4 connected to the word lines WL2, WL3 and the dummy cells 3 connected to the dummy word lines DWLLo, DWLLe have the arrangement order of the source line contact 23, the word line (or reference word line) and the bit line contact 21.

In this way, in terms of the bit line 31, the memory cells 4 connected to the word line at odd number order on one side of the cross point are associated with the reference cells 3 connected to the reference word line at odd number order on the other side. The memory cells connected to the word line at even number order on one side of the cross point are associated with the reference cells 3 connected to the reference word line at even number order on the other side.

FIG. 6 shows one example in which two word lines are arranged on each side of the cross point of the bit lines 31, 32. The number of the word lines and the number of the dummy word lines are not limited. It is desirable to conform the number of the word lines and the number of the dummy word lines on both sides of the cross point.

It is unnecessary to conform the number of the word lines and the number of the dummy word lines. The memory cells connected to the different word lines may share the same dummy cell.

In this way, in a semiconductor memory device according to the second embodiment, the bit line pairs 31, 32 are crossed in the intermediate point between the sense amplifiers 1 on both sides, thereby conforming the arrangement order of the source line contact, the word line and the bit line contact in the dummy cells 3 and the memory cells 4. Therefore, even if alignment errors occur in the manufacturing process, it is possible to correctly read out data of the memory cells 4 to be read out.

What is claimed is:

1. A semiconductor memory device, comprising:
memory cells each of which has a MIS type of transistor capable of setting one of two kinds of threshold potentials;
reference cells used for determining data stored in the memory cells, which have the same size, shape and electrical properties as those of the memory cells;
word lines connected to gates of the memory cells;
reference word lines connected to gates of the reference cells;
source line contacts connected to sources of the memory cells and the reference cells; and
bit line contacts connected to drains of the memory cells and the reference cells,
arrangement order of the source line contact, the word line and bit line contact connected to each of the memory cells is equal to arrangement order of the source line contact, the reference word line and the bit line contact connected to the reference cell corresponding to the memory cell.

2. A semiconductor memory device according to claim 1, further comprising:
sense amplifiers each of which senses and amplifies data read out from the corresponding memory cell; and
bit line pairs arranged on both sides of the sense amplifiers, each of which is connected to the corresponding sense amplifier.

3. A semiconductor memory device according to claim 2,
wherein the bit line contacts, the word lines and the source line contacts are repeatedly arranged in a predetermined order on one bit line side of each bit line pair;
the bit line contacts, the word lines and the source line contacts are repeatedly arranged in a predetermined order on the other bit line side of the bit line pair; and
the memory cells and the reference cells are connected on the same bit line.

4. A semiconductor memory device according to claim 3,
wherein the reference cell corresponding to the memory cell connected to the word line at even number order which crosses to one bit line of the bit line pair is connected to the reference word line at odd number order which crosses to the other bit line of the bit line pair, and the reference cell corresponding to the memory cell connected to the word line at odd number order which crosses to the one bit line is connected to the reference word line at even number order which crosses to the other bit line.

5. A semiconductor memory device according to claim 3,
wherein the memory cells connected to one bit lines of the bit line pair share the same reference cell connected to the other bit line of the bit line pair.

6. A semiconductor memory device according to claim 2,
wherein the memory cells arranged in a word line direction are connected to the same source line contact, the word line and the bit line contact; and
the reference cells arranged in the word line direction are connected to the same source line contact, the reference word line and the bit line contact.

7. A semiconductor memory device according to claim 3,
wherein two memory cells adjacently arranged in a bit line direction has different arrangement orders of a source, a gate and a drain from each other; and
two dummy cells adjacently arranged in a bit line direction has different arrangement orders of a source, a gate and a drain from each other.

8. A semiconductor memory device according to claim 1, further comprising:
one pair of sense amplifiers which sense and amplify data read out from the memory cells; and
bit line pairs each of which is provided corresponding to each of the sense amplifiers, connected alternatively to each sense amplifier, and arranged between the one pair of sense amplifiers,
wherein two bit lines in the bit line pair are crossed to each other not to be short-circuited between the one pair of sense amplifiers.

9. A semiconductor memory device according to claim 8,
wherein data of the memory cells connected to one bit line of the bit line pair is read out by using the reference cell connected to the one bit line, and data of the memory cell connected to the other bit line is read out by using the reference cell connected to the other bit line.

10. A semiconductor memory device according to claim 8,
wherein the bit line contacts, the word lines and the source line contacts are repeatedly connected to the bit line pair in a predetermined order.

11. A semiconductor memory device according to claim 10,
wherein the memory cells are alternatively connected to one bit line and the other bit line of the bit line pair; and
two memory cells adjacently arranged, one of which is connected to the one bit line, the other of which is connected to the other bit line, said two memory cells being connected to different word lines from each other, and connected to the same source line contact.

12. A semiconductor memory device according to claim 8,
wherein the memory cell and the corresponding reference cell are arranged on different sides from each other with respect to a cross point of the bit line pair.

13. A semiconductor memory device according to claim 12,
wherein the same number of the memory cells and the reference cells are arranged on both sides of the cross point of the bit line pair.

14. A semiconductor memory device according to claim 12,
wherein the memory cell connected to the word line at odd number order on one side with respect to the cross point of the bit line pair is associated with the reference cell connected to the reference word line at odd number order on the other side, and the memory cell connected to the word line at even number order on the one side is associated with the reference cells connected to the reference cells at even number order at the other side.

15. A semiconductor memory device according to claim 8,
wherein a cross point of the bit line pair has a plurality of wiring layers arranged above and below.
